(19) United States
(12) Patent Application Publication
(10) Pub. No.: US 2010/0008203 A1
(43) Pub. Date: Jan. 14, 2010

(54) SEMICONDUCTOR DEVICE, ITS MANUFACTURING METHOD AND OPTICAL PICKUP MODULE

(76) Inventors: Junya Furuyashiki, Kagoshima (JP); Syouzou Moribe, Kagoshima (JP); Hiroki Utatsu, Kagoshima (JP); Noriyuki Yoshikawa, Osaka (JP); Toshiyuki Fukuda, Kyoto (JP); Masanori Minamio, Osaka (JP); Hiroyuki Ishida, Osaka (JP)

Correspondence Address: MCDERMOTT WILL & EMERY LLP, 600 13TH STREET, NW, WASHINGTON, DC, 20005-3096, US

(21) Appl. No.: 12/525,779

(22) PCT Filed: Mar. 10, 2008
(86) PCT No.: PCT/JP2008/000509

§ 371 Date: Aug. 4, 2009

(30) Foreign Application Priority Data
Mar. 14, 2007 (JP) 2007-064777

(51) Int. Cl. G11B 7/00; H01L 31/02; H01L 21/50

(52) U.S. Cl. 369/100; 257/434; 438/116; 257/E31.11; 257/E21.499; G9B/7

(57) ABSTRACT

A semiconductor element is mounted on a rectangular base of a package including the base and ribs provided on a pair of opposite external edges of the base. Electrode pads of the semiconductor element and connection electrodes provided on rib upper surfaces are connected to each other by metal wires. On the rib upper surfaces, spacers are provided at locations closer to the outside than the connection electrodes. A transparent lid adheres to the upper surfaces of the spacers to cover the entire surface of the package. The height of the spacers is greater than the diameter of the metal wires.

### TECHNICAL FIELD

The present invention relates to semiconductor devices, methods for fabricating the devices, and optical pickup modules.

### BACKGROUND ART

Conventional optical disk drives for reading signals from optical disks such as DVDs are provided with optical pickup modules in each of which a semiconductor laser for emitting light for reading, and a photodetector for receiving feedback light reflected from optical disks are mounted on the same base.

As disclosed in Patent Document 1, an optical disk drive includes an optical pickup module located under the optical recording surface of an optical disk and configured to move along the radius of the optical disk. Because of this configuration, size reduction of the optical disk drive requires miniaturization of the optical pickup module, which further requires miniaturization of the photodetector.

In a conventional photodetector, a photoreceiver such as a solid-state image sensor is housed in a rectangular-solid package, and a transparent member is used at the surface of the package facing the light-receiving surface of the photoreceiver (see, for example, Patent Documents 3 and 4). In the photodetectors (i.e., solid-state image sensors) of Patent Document 3 and 4, a photoreceiver is fixed to the bottom of a package, and electrodes of a photoreceiver are wire bonded to connection electrode portions provided on the bottom of the package. In this structure, the bottom of the package needs to have an area on which the connection electrode portions are provided. Consequently, the size of the photodetector increases accordingly.

On the other hand, as illustrated in FIG. 15, in order to reduce the size of an optical pickup module, Patent Document 2, for example, discloses a semiconductor device including: a base 201 having an upper principal surface over which a recessed space 201a is provided with electrode pads 204 formed on the upper surface of a side wall 201c surrounding the recessed space 201a; a semiconductor element 202 placed at the bottom 201b of the recessed space 201a, having an upper surface on a center portion of which a light-receiving part 202a is provided, and having a peripheral portion on which electrodes 203 are formed; bonding wires 205 electrically connecting the electrodes 203 to the electrode pads 204; a resin layer 206 provided on the upper surface of the side wall 201c along the entire circumference thereof to cover the electrode pads 204; and a transparent lid 207 adhering to the top of the resin layer 206 to seal the semiconductor element 202.

Patent Document 1: Japanese Laid-Open Patent Publication No. 2001-56950

Patent Document 2: Japanese Laid-Open Patent Publication No. 2002-164524

Patent Document 3: Japanese Laid-Open Patent Publication No. 2005-64292

Patent Document 4: Japanese Laid-Open Patent Publication No. 2005-79537

### DISCLOSURE OF INVENTION

### Problems that the Invention is to Solve

In the semiconductor device disclosed in Patent Document 2, the electrode pads are provided on the upper surface of the side wall for mounting the transparent lid thereon, and thus the semiconductor device can be miniaturized. However, the adhesive is provided on the bonding wires to bond the transparent lid, and thus it is still very difficult to make the transparent lid stay always securely fixed in parallel with the light-receiving surface of the semiconductor element.

It is therefore an object of the present invention to provide a semiconductor device in which a lid or a transparent member for protecting a semiconductor element can be securely fixed, and which can be reduced in overall size.

### Means of Solving the Problems

To achieve the object, a semiconductor device according to the present invention includes: a semiconductor element; and a package on which the semiconductor element is mounted. The package includes a base which is substantially rectangular and has a mounting surface on which the semiconductor element is mounted, and ribs respectively provided on a pair of opposite external edges of the mounting surface and extending along the opposite external edges. A connection electrode and a spacer are provided on an upper surface of each of the ribs. The connection electrode is connected to the semiconductor element by a metal wire. The spacer is located farther from the semiconductor element than the connection electrode, has a height greater than a diameter of the metal wire, and extends along an external edge of the upper surface of the rib.

The expression, “substantially rectangular,” herein does not strictly mean a rectangle in terms of mathematics, and includes rectangles whose sides partly project outward or are dented inward.

In a preferred embodiment, the semiconductor element is an optical element, and a transparent member is placed on the semiconductor element.

In another preferred embodiment, a lid is placed on, and adheres to, the spacer.

A method for fabricating a semiconductor device according to the present invention is a method for fabricating a semiconductor device including a semiconductor element and a package on which the semiconductor element is mounted. The method includes: preparing a package-assembled board including a plurality of parallel trenches, two lines of connection electrodes provided on an upper surface of a side wall of each of the trenches and arranged along the trench, and a spacer provided between the two lines of connection electrodes and extending along the trench; placing a plurality of semiconductor elements in each of the trenches in a direction along which the trench extends; connecting the semiconductor element and the connection electrodes to each other by metal wires; and cutting the package-assembled board along a line between the two lines of connection electrodes, thereby dividing the package-assembled board.

An optical pickup module according to the present invention includes: the semiconductor device described above; a laser module; and a beam splitter. The semiconductor element included in the semiconductor device is a photoreceiver.

The laser module preferably includes: a blue-violet laser device configured to emit light having a peak wavelength ranging from 385 nm to 425 nm, both inclusive; and a dual-wavelength laser device configured to emit light having a peak wavelength ranging from 630 nm to 670 nm, both inclusive, and light having a peak wavelength ranging from 760 nm to 800 nm, both inclusive. The peak wavelength of emitted light is a wavelength at which the intensity is at the maximum in a spectrum of the light.

### Effects of the Invention

A semiconductor device according to the present invention has a structure in which connection electrode for connection to a semiconductor element are provided on the upper surfaces of ribs and spacers whose height is greater than the diameter of metal wires are provided on the ribs. As a result, the semiconductor device itself can be miniaturized.

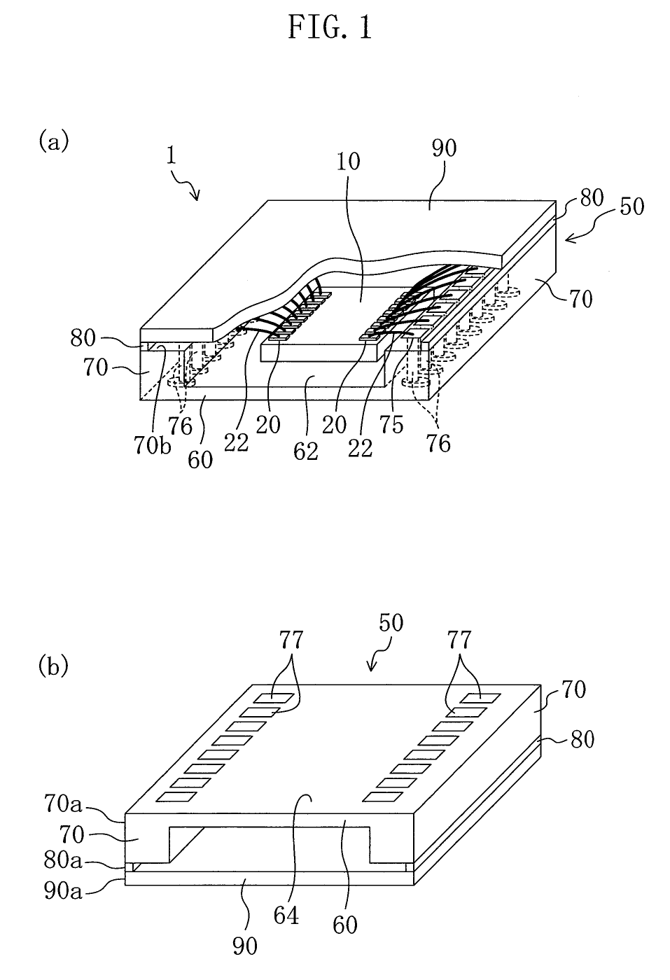

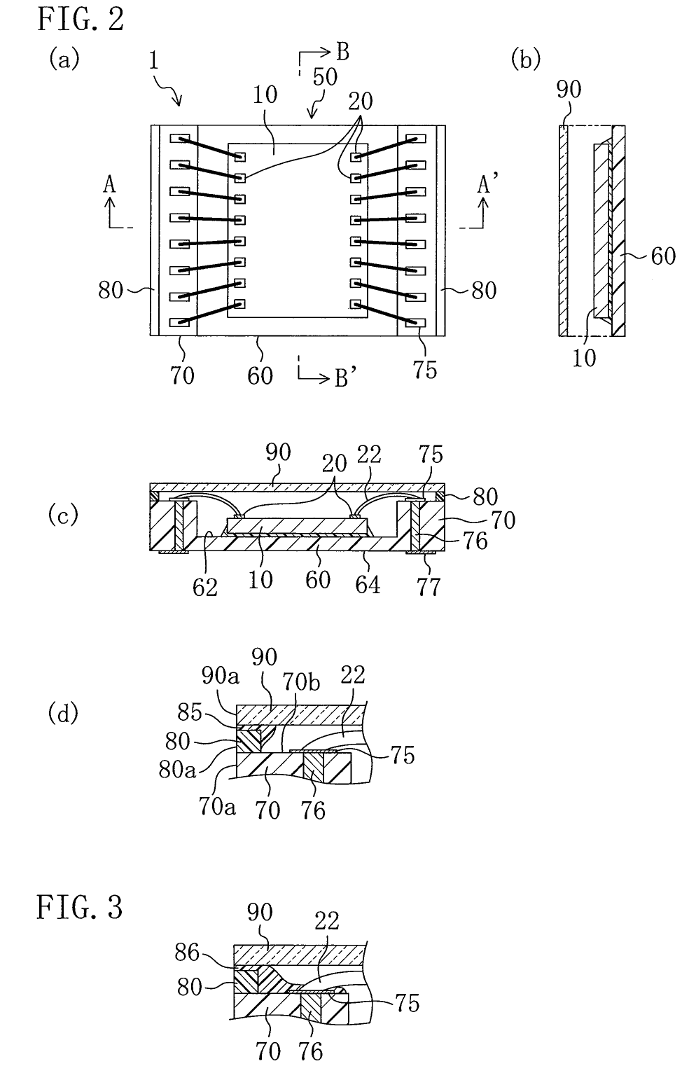

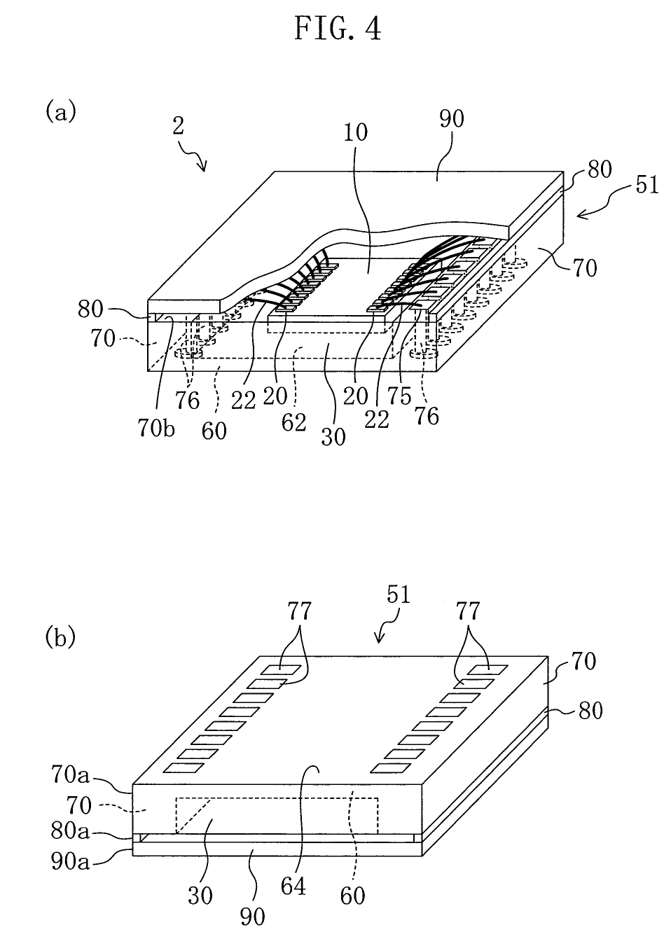

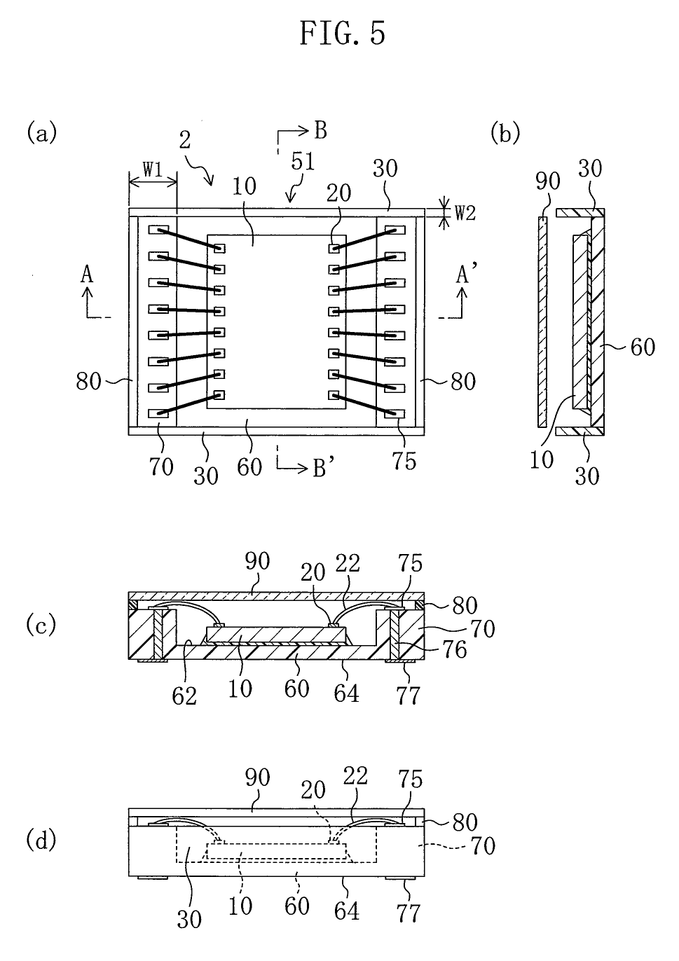

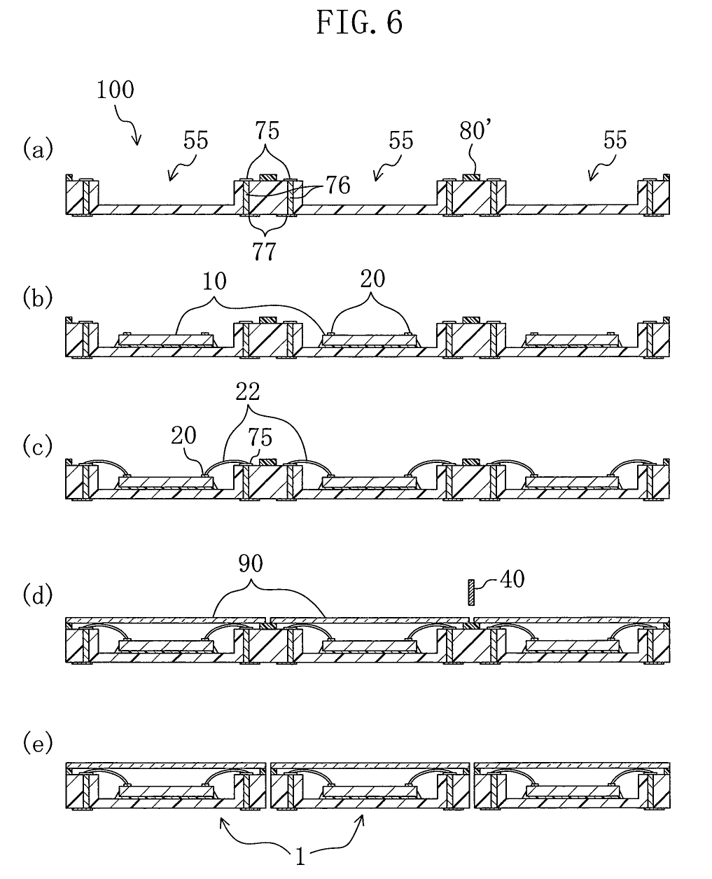

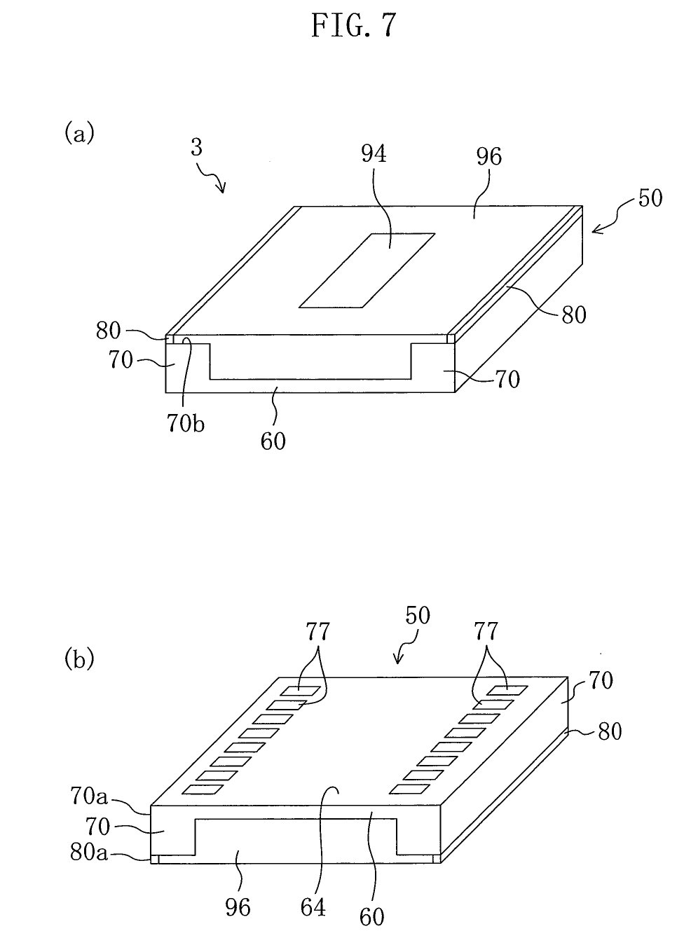

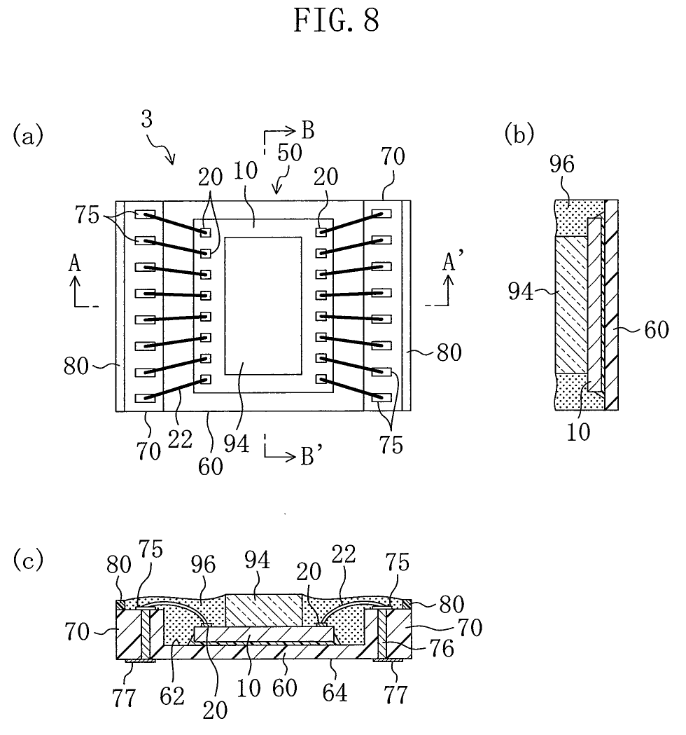

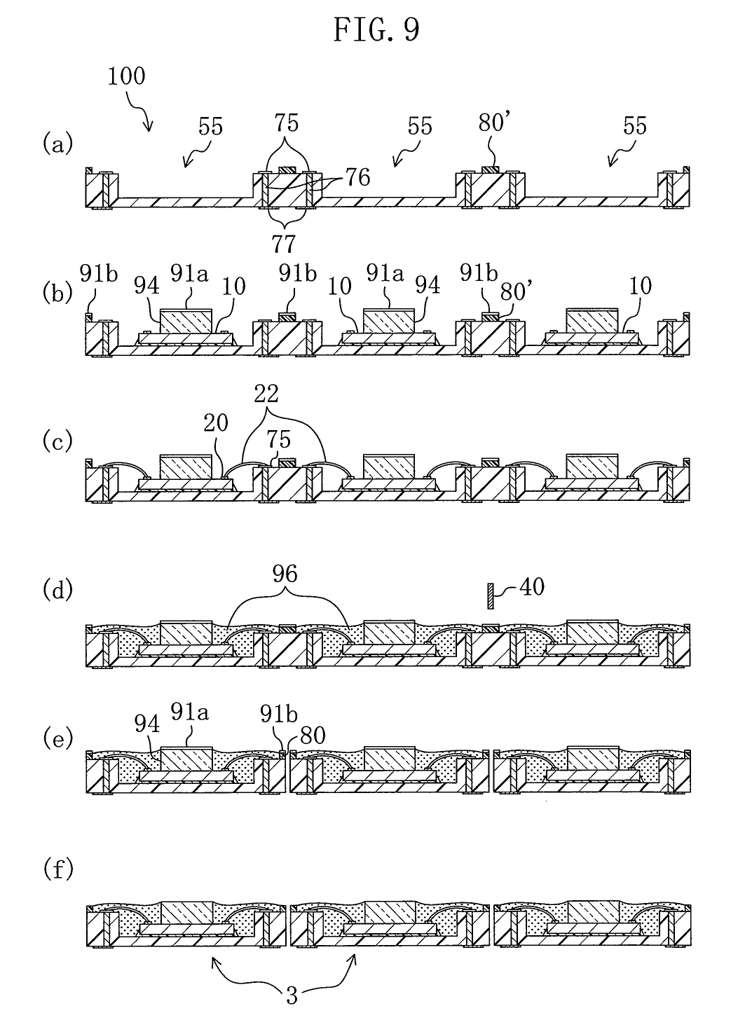

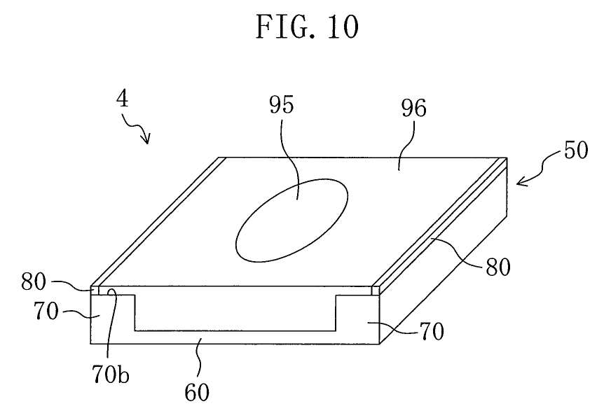

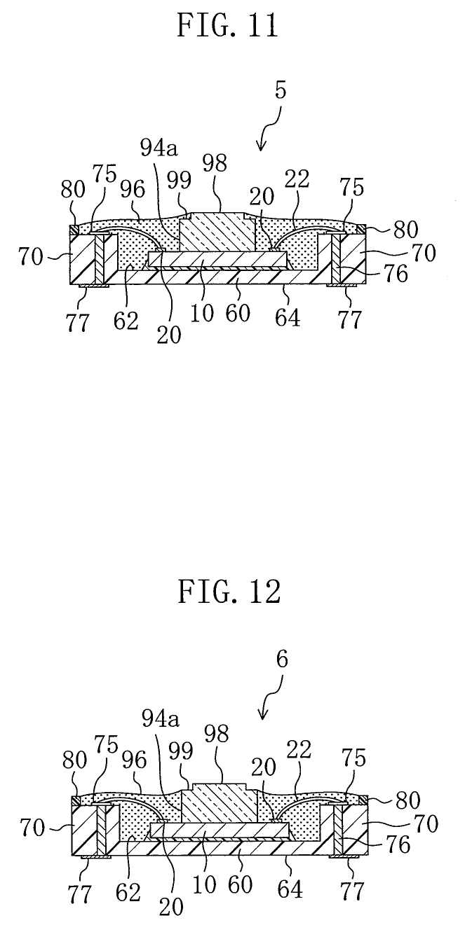

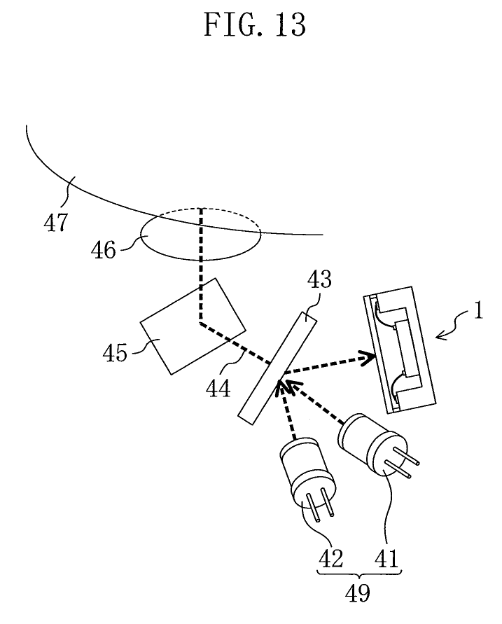

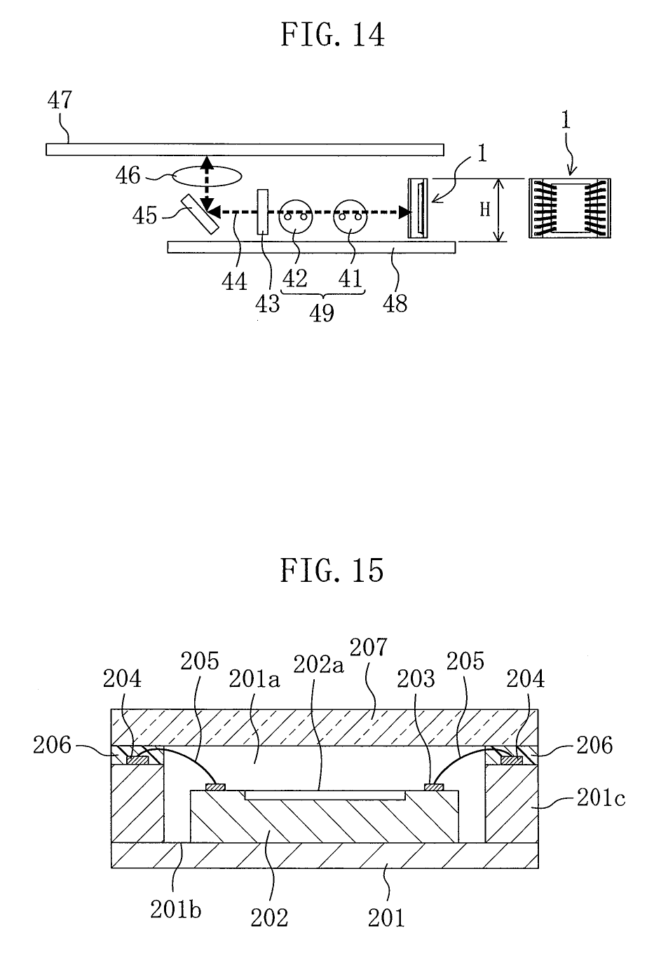

### BRIEF DESCRIPTION OF DRAWINGS

[FIG. 1] FIG. 1(a) is a view, partially broken away, illustrating a semiconductor device according to a first embodiment. FIG. 1(b) is a bottom view corresponding to FIG. 1(a).

[FIG. 2] FIG. 2(a) is a top view illustrating the semiconductor device of the first embodiment on the assumption that a lid is transparent. FIG. 2(b) is a cross-sectional view taken along line B-B′ in FIG. 2(a). FIG. 2(c) is a cross-sectional view taken along line A-A′ in FIG. 2(a). FIG. 2(d) is a partially enlarged view corresponding to FIG. 2(c).

[FIG. 3] FIG. 3 is an enlarged cross-sectional view illustrating a portion of a semiconductor device according to a second embodiment.

[FIG. 4] FIG. 4(a) is a view, partially broken away, illustrating a semiconductor device according to a third embodiment. FIG. 4(b) is a bottom view corresponding to FIG. 4(a).

[FIG. 5] FIG. 5(a) is a top view of the semiconductor device of the third embodiment on the assumption that a lid is transparent. FIG. 5(b) is a cross-sectional view taken along line B-B′ in FIG. 5(a). FIG. 5(c) is a cross-sectional view taken along line A-A′ in FIG. 5(a). FIG. 5(d) is a side view.

[FIG. 6] FIG. 6 shows fabrication of the semiconductor device of the first embodiment in chronological order.

[FIG. 7] FIG. 7(a) is a perspective view illustrating a semiconductor device according to a fourth embodiment. FIG. 7(b) is a bottom view corresponding to FIG. 7(a).

[FIG. 8] FIG. 8(a) is a top view illustrating the semiconductor device of the fourth embodiment with an encapsulating resin omitted. FIG. 8(b) is a cross-sectional view taken along line B-B′ in FIG. 8(a). FIG. 8(c) is a cross-sectional view taken along line A-A′ in FIG. 8(a).

[FIG. 9] FIG. 9 shows fabrication of the semiconductor device of the fourth embodiment in chronological order.

[FIG. 10] FIG. 10 is a perspective view illustrating a semiconductor device according to a fifth embodiment.

[FIG. 11] FIG. 11 is a cross-sectional view illustrating a semiconductor device according to a sixth embodiment.

[FIG. 12] FIG. 12 is a cross-sectional view illustrating another semiconductor device according to the sixth embodiment.

[FIG. 13] FIG. 13 is a perspective view schematically illustrating an optical pickup module according to the first embodiment.

[FIG. 14] FIG. 14 is a front view schematically illustrating the optical pickup module of the first embodiment.

[FIG. 15] FIG. 15 is a cross-sectional view illustrating a conventional semiconductor device including a photoreceiver.

### DESCRIPTION OF SYMBOLS

1, 2, 3, 4, 5, 6 semiconductor device

10 semiconductor element

22 metal wire

30 plate-like side wall

41 first laser device

42 second laser device

43 beam splitter

45 mirror

46 objective lens

47 optical disk

49 laser module

50, 51 package

60 base

62 mounting surface

64 non-mounting surface

70 rib

70a rib external side wall surface

70b rib upper surface

75 connection electrode

76 internal interconnection

77 external-connection portion

80 spacer

80a spacer external side wall surface

85, 86 adhesive

90 lid

90a lid side wall surface

94, 94a, 95 transparent member

96 encapsulating resin

100 package-assembled board

### BEST MODE FOR CARRYING OUT THE INVENTION

Hereinafter, embodiments of the present invention will be specifically described with reference to the drawings. In the drawings, components having substantially the same functions are denoted by the same reference character for simplicity of the description.

### Embodiment 1

### —Semiconductor Device—

A semiconductor device according to a first embodiment is a photodetector employing an integrated photoreceiver as a semiconductor element. The semiconductor element may be a photoreceiver such as a photodiode, a phototransistor, and a photo IC, or a light-emitting element such as an LED and a semiconductor laser.

Specifically, as illustrated in FIG. 1, in a semiconductor device 1 of this embodiment, a semiconductor element 10 is housed in a recess of a recessed package 50 having a “U” shape in cross section, and a transparent flat lid 90 covers the recess. FIGS. 2(a) through 2(d) also illustrate the semiconductor device 1 of this embodiment. However, for convenience of description, the lid 90 is considered to be transparent, and is not shown in FIG. 2(a). In the same manner, for convenience of description, an adhesive 85 fixing the lid 90 is not shown in FIG. 1 and FIGS. 2(a) and 2(c).

The package 50 of this embodiment includes: a rectangular base 60; two ribs 70, 70 respectively extending along a pair of opposite sides of the rectangle; and spacers 80, 80 respectively provided on the upper surfaces of the ribs 70, 70. The ribs 70, 70 respectively project upward from a pair of opposite external edges of a rectangular mounting surface 62 of the base 60 on which the semiconductor element 10 is mounted. Each of the ribs 70, 70 is in the shape of a rectangular solid extending along the external edge of the mounting surface 62. The boundaries between the base 60 and the ribs 70, 70 are not clearly shown. However, since the ribs 70, 70 are placed on the base 60, the level of the mounting surface 62 can be defined as the boundaries.

A plurality of internal interconnections (i.e., buried interconnections) 76, 76 are provided in each of the ribs 70, 70. The internal interconnections 76 are connected to connection electrodes 75 at the rib upper surface 70b, and are connected to external-connection portions 77 at the opposite surface (i.e., a non-mounting surface 64). The spacers 80, 80 are located closer to the outside than the connection electrodes 75 on the rib upper surfaces 70b, and respectively extend in parallel with the ribs 70, 70.

The semiconductor element 10 is rectangular, and a plurality of electrode pads 20, 20 are respectively aligned along a pair of two opposite sides of the semiconductor element 10 on one surface of the semiconductor element 10. The surface of the semiconductor element 10 opposite the surface on which the electrode pads 20, 20 are provided is mounted on the mounting surface 62, and is fixed to the mounting surface 62 with an adhesive. With this configuration, the semiconductor element 10 is mounted on the package 50 in such a manner that the electrode pads 20, 20 are aligned substantially in parallel with the direction along which the ribs 70, 70 extend. The electrode pads 20, 20 are connected to the connection electrodes 75 on the rib upper surfaces 70b by metal wires 22.

The spacers 80, 80 are located farther from the semiconductor element 10 than the connection electrodes 75 on the rib upper surfaces 70b, and extend in parallel with the ribs 70, 70. The lid 90 is placed on the spacers 80, 80, and is fixed with an adhesive 85. The adhesive 85 is sandwiched between the spacers 80 and the lid 90. The adhesive 85 slightly extends out from the spacers 80 toward the inside of the package 50, but does not adhere to the metal wires 22. That is, the metal wires 22 are exposed to air except for portions thereof in contact with the connection electrodes 75 and the electrode pads 20. In this regard, this embodiment differs from the technique disclosed in Patent Document 2. In the technique of Patent Document 2, the absence of spacers prevents accurate positioning of the lid in terms of height, resulting in a problem in parallelizing the lid. In addition, as another problem, a difference in expansion coefficient between the adhesive and metal causes breaks in the metal wires at the boundary between portions of the metal wires buried in the adhesive, and portions of the metal wires exposed to air. In contrast, such problems do not arise in this embodiment. Moreover, in the semiconductor device of Patent Document 2, bonding wires are not fixed yet in bonding the transparent lid, but float in the adhesive in the state of a liquid. Accordingly, while this adhesive is hardened, contraction stress due to the hardening is applied to the bonding wires and connection portions between the bonding wires and the electrodes, and might cause peeling of the connection portions. In contrast, such a problem does not arise in this embodiment.

As illustrated in FIG. 2(d) that is an enlarged view of an upper portion of the left rib 70 in FIG. 2(c), the height of the spacers 80, 80 is greater than the diameter of the metal wires 22, and bonding of the metal wires 22 to the connection electrodes 75 is the second bonding. Thus, it is possible to prevent the lid 90 placed on the spacers 80, 80 from being in contact with the metal wires 22 and pushing the metal wires 22, resulting in high connection reliability of the metal wires 22. In addition, since the height of the spacers 80, 80 is set less than or equal to twice as large as the diameter of the metal wires 22, the thickness of the semiconductor device 1 can be reduced, resulting in miniaturization of the semiconductor device 1.

At each side wall surface of the semiconductor device 1, a rib external side wall surface 70a, a spacer external side wall surface 80a, and a lid side wall surface 90a are flush with one another. Accordingly, the length of the semiconductor device 1 between the ribs 70, 70 can be reduced, thus contributing to miniaturization. In addition, the adhesive 85 is also flush with these side wall surfaces, i.e., does not extends out from the side wall surface of the semiconductor device 1 outward. The external side wall surfaces herein refer to the side wall surfaces of the ribs 70, 70 and the spacers 80, 80 opposite the side wall surfaces thereof facing the semiconductor element 10.

### —Method for Fabricating Semiconductor Device—

A method for fabricating a semiconductor device 1 according to this embodiment is now described.

First, a package-assembled board 100 illustrated in FIG. 6(a) is prepared. In the package-assembled board 100, a plurality of packages 50 as described above are arranged, and rib external side wall surfaces 70a of adjacent ones of the packages 50 are united. In the direction along which the ribs extend, a plurality of packages 50 are also arranged and united.

This package-assembled board 100 can be fabricated by a known method. For example, a plurality of parallel trenches 55, 55, 55 are formed in a plastic or ceramic plate, and two lines of through holes are formed between each adjacent two of the trenches 55, 55 in parallel with the trenches 55. Then, the through holes are filled with a conductive member, thereby forming internal interconnections 76. Connection electrodes 75 and external-connection portions 77 are respectively provided on the top and bottom of the internal interconnections 76. Thereafter, spacers 80′ are provided in such a manner that each of the spacers 80′ is located between each adjacent two lines of the connection electrodes 75. In this manner, fabrication of the package-assembled board 100 is completed.

Next, a plurality of semiconductor elements 10 are mounted on, and fixed to, each of the bottom surfaces of the trenches 55, 55, 55 along the direction in which the trenches 55, 55, 55 extend. In this manner, the configuration illustrated in FIG. 6(b) is obtained.

Then, electrode pads 20 of the semiconductor elements 10 are wire bonded to the connection electrodes 75. In this manner, as shown in FIG. 6(c), a configuration in which the electrode pads 20, 20 and the connection electrodes 75 are connected to each other by metal wires 22 is obtained.

Thereafter, an adhesive (not shown) is applied onto the upper surfaces of the spacers 80′. Then, transparent lids 90 for the respective semiconductor elements 10 are placed on the spacers 80′, and are bonded and fixed to the spacers 80′. Each of the lids 90 covers an associated one of the semiconductor elements 10. This configuration is shown in FIG. 6(d). The adhesive is not shown in FIGS. 6(d) and 6(e).

Subsequently, the board is cut with a dicing saw 40 in such a manner that two lines of the connection electrodes 75 between adjacent two of the trenches 55, 55 are separated from each other. At this time, each of the spacers 80′ is divided into two at a middle portion thereof. This state after the division is shown in FIG. 6(e). In this manner, side wall surfaces become with one another. Thereafter, adjacent ones of the semiconductor elements 10 disposed perpendicularly to the direction along which the trenches 55 extend are separated from each other. In this manner, individual semiconductor devices 1 are obtained.

The above-described method for fabricating semiconductor devices 1 is merely an example. The fabrication method of this embodiment is not limited to this example. The internal interconnections may be formed before the trenches 55 are formed. The lids may be placed after the division of the board along lines each located between two lines of the connection electrodes. The trenches may be formed by cutting, by using laser light, or by arranging a plurality of rods which are rectangular in cross section on the plate and bonding the rods to the plate.

### —Optical Pickup Module—

FIG. 13 is a perspective view schematically illustrating a configuration in which an optical pickup module according to this embodiment is placed under an optical disk 47. FIG. 14 is a side view of the configuration. The semiconductor device 1 at the right side of FIG. 14 is shown in order to depict the light-receiving surface of the semiconductor device 1 (photodetector) mounted on a support 48, which is located at the left of the right-side semiconductor device 1, with the semiconductor device 1 rotated 90° with respect to the vertical axis. The illustration does not mean that two semiconductor devices 1 are provided in the optical pickup module.

This optical pickup module includes the above-described semiconductor device 1 (photodetector), first and second laser devices 41 and 42, a beam splitter 43, a mirror 45, and an objective lens 46. The first and second laser devices constitute a laser module 49. Light 44 emitted from the first and second laser devices 41 and 42 passes through the beam splitter 43, is reflected on the mirror 45, and then strikes an information-recording surface of the optical disk 47 through the objective lens 46. The light 44 is then reflected on the information-recording surface, and enters the semiconductor device 1 by way of the objective lens 46, the mirror 45, and the beam splitter 43.

In this case, the first laser device 41 is a blue-violet laser device configured to emit laser light having a peak wavelength of 405 nm. The second laser device 42 is a dual-wavelength laser device configured to emit laser light with two wavelengths: red laser light having a peak wavelength of 650 nm; and infrared laser light having a peak wavelength of 780 nm.

Components constituting the optical pickup module are mounted on the support 48, and this support 48 is placed under the information-recording surface of the optical disk 47. Under the rotating optical disk 47, the optical pickup module moves along the radius of the optical disk 47. The surface of the support 48 on which the components are mounted is in parallel with the information-recording surface of the optical disk 47.

For convenience in establishing interconnection, the semiconductor device 1 is positioned in such a manner that the direction along which the ribs 70, 70 extend is perpendicular to the support 48, i.e., to the information-recording surface of the optical disk 47. With this positioning, a plurality of external-connection portions 77, 77, . . . of the semiconductor device 1 are arranged in two lines perpendicularly to the mounting surface of the support 48. Accordingly, wires drawn from the external-connection portions 77, 77, . . . to establish connection to the outside are arranged within the height H of the semiconductor device 1 from the mounting surface of the support 48, resulting in reduction of the height of the entire optical pickup module.

As described above, the ribs 70, 70 of the semiconductor device 1 extend perpendicularly to the support 48, and no ribs extend in parallel with the support 48. This configuration allows the height H of the semiconductor device 1 to be made approximately equal to the length of one side of the semiconductor element 10. As a result, the entire optical pickup module can be thinner, and smaller in size.

In the semiconductor device 1 of this embodiment, the connection electrodes 75 are not provided on the mounting surface 62 of the base 60, but are provided on the upper surfaces 70b of the ribs 70, 70 for placing the lid 90. This structure can reduce the size of the semiconductor device 1. In addition, the spacers 80, 80 provided on the ribs 70, 70 can increase the degree of parallelism of the lid 90.

### Embodiment 2

A semiconductor device according to a second embodiment differs from the semiconductor device 1 of the first embodiment only in that an adhesive is attached to portions of metal wires. In the other aspects, the semiconductor device of the second embodiment is the same as that of the first embodiment, and thus only different aspects are now described.

As illustrated in FIG. 3 that is an enlarged view of an upper portion of a rib 70, in the semiconductor device of this embodiment, a larger amount of an adhesive 86 than in the first embodiment is applied, and the adhesive 86 extends to a portion of a metal wire 22 in contact with a connection electrode 75. This structure can make the adhesive strength between a lid 90 and a package 50 greater than that in the first embodiment, thus allowing the lid 90 to be firmly fixed. Since the adhesive 86 is attached only to a portion of the metal wire 22 in contact with the connection electrode 75, no breaks occur in the metal wire 22.

### Embodiment 3

A semiconductor device according to a third embodiment differs from the semiconductor device 1 of the first embodiment only in that plate-like side walls are additionally provided. In the other aspects, the semiconductor device of the third embodiment is the same as that of the first embodiment, and thus only different aspects are now described.

FIGS. 4(a) and 4(b) and FIGS. 5(a) through 5(d) illustrate a semiconductor device 2 according to this embodiment. In these drawings, an adhesive provided on spacers 80, 80 are not shown. In the semiconductor device 2 of this embodiment, plate-like side walls 30 are respectively provided along a pair of external edges of a base 60 different from a pair of external edges along which ribs 70, 70 are provided. Each of the plate-like side walls 30 extends from an end, in the longitudinal direction, of one of the ribs 70 to an end of the other rib 70. That is, a package 51 according to this embodiment is obtained by adding the plate-like side walls 30, 30 to the package 50 of the first embodiment.

The plate-like side walls 30, together with rib external side wall surfaces 70a, constitute the four sides of the package 51. The package 51 has a recessed shape formed by removing the upper face from a box of a rectangular solid. In this recess, a semiconductor element 10 is placed.

The height of the plate-like side walls 30 from a mounting surface 62 of the base 60 is equal to that of the ribs 70. The width W2 (i.e., the width perpendicular to the longitudinal direction) of each of the upper surfaces of the plate-like side walls 30 is smaller than the width W1 (i.e., the width perpendicular to the longitudinal direction) of each of the upper surfaces of the ribs 70. The plate-like side walls 30 can prevent dirt and dust from entering the semiconductor device 2 from the outside, thus preventing the dirt and dust from accumulating on the light-receiving surface of the semiconductor element 10. The length of the semiconductor device 2 along which the ribs 70, 70 extend is larger than that of the semiconductor device 1 of the first embodiment by a distance corresponding to the widths W2×2 of the two plate-like side walls 30, 30. However, since the width W2 is smaller than the width W1 of each of the ribs 70, 70, the increase in the length is suppressed to a small value. The width W2 is preferably less than or equal to ½ of the width W1, and more preferably less than or equal to ¼ of the width W1. It is sufficient that the width W2 is greater than or equal to 10 μm.

The semiconductor device 2 of this embodiment can be fabricated in a similar manner to that for the semiconductor device of the first embodiment. That is, after fabrication of the semiconductor device of the first embodiment, the plate-like side walls 30, 30 are attached to the semiconductor device, thereby completing a semiconductor device 2 of this embodiment.

### Embodiment 4

### —Semiconductor Device—

A semiconductor device according to a fourth embodiment differs from the semiconductor device of the first embodiment in that a transparent member in the shape of a plate replaces the transparent flat lid and is placed over a semiconductor element, and that a trench in the package is filled with an encapsulating resin in such a manner that side surfaces of the transparent member and metal wires are buried in the resin. Now, the fourth embodiment, particularly aspects thereof different from those of the first embodiment, is described. The same aspects as those of the first embodiment may be omitted in the following description.

FIGS. 7(a) and 7(b) and FIGS. 8(a) through 8(c) illustrate a semiconductor device 3 according to this embodiment. In FIG. 8(a), an encapsulating resin 96 is not shown for convenience of description. In this embodiment, a package 50, a semiconductor element 10, spacers 80, 80, ribs 70, 70, and metal wires 22 are the same as those in the first embodiment, and a configuration for connecting the semiconductor element 10 and connection electrodes 75 is also the same as that of the first embodiment.

The semiconductor element 10 mounted on the package 50 is connected to connection electrodes 75 by the metal wires 22. A plate-like transparent member 94 is placed on the semiconductor element 10 to cover the light-receiving surface of the semiconductor element 10 with a transparent adhesive interposed between the semiconductor element 10 and the transparent member 94. The transparent member 94 is a plate-like member having a rectangular upper surface and made of glass, and adheres to the semiconductor element 10.

In addition, components provided in a trench (recess) of the package 50 except for the upper surface of the transparent member 94 and the upper surfaces of the spacers 80, 80 are encapsulated with the encapsulating resin 96. Specifically, side surfaces of the transparent member 94, the upper surfaces of the ribs 70, 70, and the metal wires 22, for example, are buried in the encapsulating resin 96. When viewed from above the semiconductor device 2 of this embodiment, only the upper surface of the transparent member 94 and the upper surfaces of the spacers 80, 80 are exposed, and the other components are covered with the encapsulating resin 96. Accordingly, no dirt and dust accumulate on the light-receiving surface of the semiconductor element 10, electrode pads 20, the connection electrodes 75, and the metal wires 22, thus avoiding failures such as short circuits caused by dirt and dust. The encapsulating resin is preferably one of a thermosetting epoxy resin, a filler-added resin containing, for example, SiO₂, and a resin which contains a dye and exhibits a light-blocking property, for example.

The encapsulating resin 96 is a high-viscosity liquid when filling the trench of the package 50, and is then cured. At the side wall surfaces of the semiconductor device 3 except for the rib external side wall surfaces 70a, the encapsulating resin 96 is flush with the end surfaces of the ribs 70, 70. The height of the spacers 80, 80 is greater than the diameter of the metal wires 22. Accordingly, when the trench is filled with the encapsulating resin 96 to a level approximately equal to that of the upper surfaces of the spacers 80, 80, the metal wires 22 are completely buried in the encapsulating resin 96. Unlike the technique of Patent Document 2, the structure of this embodiment can prevent breaking of the metal wires 22, and thus connection portions between the metal wires 22 and the electrode pads 20, 20 and between the metal wires 22 and the connection electrodes 75 are fixed, thus enhancing connection reliability. In addition, since the upper surface of the transparent member 94 is exposed and the side surfaces of the transparent member 94 are buried in the encapsulating resin 96, only light that has passed through the upper surface of the transparent member 94 reaches the light-receiving surface of the semiconductor element 10. Even when light enters the side surfaces of the transparent member 94, such light does not reach the light-receiving surface. Consequently, stray light (i.e., diffuse reflection of light) can be eliminated, and thus optical properties can be enhanced.

With respect to the height (i.e., distance) from the mounting surface 62 of the base 60, the height of the upper surface of the transparent member 94 is larger than that of the upper surfaces of the spacers 80, 80. Accordingly, in placing the semiconductor device 3 in the optical pickup module, the upper surface of the transparent member 94 that is parallel to the light-receiving surface of the semiconductor element 10 and has a large area can be easily used as a reference surface for the placement. In addition, accuracy in the placement in the optical pickup module can be easily enhanced. Further, the placement can be easily performed for a short period of time.

### —Method for Fabricating Semiconductor Device—

A method for fabricating a semiconductor device 3 according to this embodiment is now described. Description of process steps already described in the first embodiment is omitted or simplified.

First, a package-assembled board 100 as illustrated in FIG. 9(a) is prepared. This package-assembled board 100 is identical to that used in the first embodiment.

Next, a plurality of semiconductor elements 10 are sequentially placed on, and fixed to, the bottom surfaces of the trenches 55, 55, . . . along the direction in which the trenches 55, 55, . . . extend. Then, transparent members 94 are placed on the light-receiving surfaces of the semiconductor elements 10, and are fixed with a transparent adhesive. At this time, protective sheets 91a are provided on the upper surfaces of the transparent members 94. Protective sheets 91b are then provided on the upper surfaces of the spacers 80′. In this manner, a configuration as illustrated in FIG. 9(b) is obtained.

Then, electrode pads 20 of the semiconductor elements 10 are wire bonded to connection electrodes 75. In this manner, as illustrated in FIG. 9(c), the electrode pads 20 and the connection electrodes 75 are connected to each other by metal wires 22.

Thereafter, the trenches 55 are filled with an encapsulating resin 96. This filling may be achieved by potting or injection molding. At this time, the entire upper surfaces of the transparent members 94 and the upper surfaces of the spacers 80′ are covered with the protective sheets 91a and 91b. This structure ensures that the upper surfaces of the transparent members 94 and the upper surfaces of the spacers 80′ are not covered with the encapsulating resin 96 and are exposed. FIG. 9(d) shows a state in which the encapsulating resin 96 fills the trenches, and is cured.

Subsequently, the board is cut with a dicing saw 40 in such a manner that two lines of the connection electrodes 75 between adjacent two of the trenches 55, 55 are separated from each other. At this time, each of the spacers 80′ is divided into two at a middle portion thereof. The state after the separation is shown in FIG. 9(e). In this manner, side wall surfaces are made flush with one another.

Then, the protective sheets 91a and 91b are peeled off from the transparent members 94 and the spacers 80′, thereby obtaining a state illustrated in FIG. 9(f). Thereafter, adjacent ones of the semiconductor elements 10 arranged perpendicularly to the direction along which the trenches 55 extend are separated from each other. In this manner, individual semiconductor devices 3 are obtained. It should be noted that because of compression of the encapsulating resin 96 during curing, the upper surface of the encapsulating resin 96 is located several micrometers below the upper surfaces of the transparent members 94 and the upper surfaces of spacers 80.

As the semiconductor device 1 of the first embodiment, the semiconductor device 3 of this embodiment can also be made smaller in size than conventional semiconductor devices.

### Embodiment 5

A semiconductor device according to a fifth embodiment differs from the semiconductor device 3 of the fourth embodiment only in the shape of a transparent member. In the other aspects, the semiconductor device of the fifth embodiment is the same as that of the fourth embodiment, and thus only different aspects are now described.

As illustrated in FIG. 10, a transparent member 95 in a semiconductor device 4 according to this embodiment is in the shape of a plate having a circular upper surface. Since the transparent member 95 is in the shape of a circular plate, an encapsulating resin 96 is likely to be uniformly applied onto the entire side surface of the transparent member 95.

This embodiment has the same advantages as those of the fourth embodiment.

### Embodiment 6

A semiconductor device according to a sixth embodiment differs from the semiconductor device 3 of the fourth embodiment only in the shape of a transparent member. In the other aspects, the semiconductor device of the sixth embodiment is the same as that of the fourth embodiment, and thus only different aspects are now described.

FIG. 11 is a cross-sectional view illustrating a semiconductor device 5 according to this embodiment. The upper surface of a transparent member 94a is stepped to have: a top surface 98 located in a middle portion of this upper surface and corresponding to the shape and size of the optical functional surface of a semiconductor element 10; and stepped surfaces 99 located below the top surface 98 at a distance corresponding to the steps. An encapsulating resin 96 covers the stepped surfaces 99, but does not cover the top surface 98. The presence of the stepped surfaces 99 in this manner ensure that a smaller area of the top surface 98 is covered with the encapsulating resin 96, resulting in ensuring entering of necessary light into the optical functional surface of the semiconductor element 10 or in efficient emission of light from the optical functional surface.

Alternatively, as illustrated in FIG. 12, none of stepped surfaces 99 and a top surface 98 of a semiconductor device 6 may be covered with an encapsulating resin 96.

### Other Embodiments

The foregoing embodiments are merely examples of the present invention, and do not limit the present invention.

The external-connection portions may be provided on an area except for the non-mounting surface of the board. For example, the external-connection portions may be provided on the rib external side wall surfaces, or may be continuously provided from the mounting surface to the rib external side wall surfaces. The external-connection portions and the connection electrodes do not need to be connected by through electrodes provided in the ribs, and may be connected by wires provided along the side wall surfaces of the ribs.

The semiconductor element does not need to be a solid-state image sensor, and may be a photoreceiver such as a photocoupler or a light-emitting element such as an LED and a laser device. Further, the semiconductor element does not need to be an optical device, and may be a SAW device, an oscillator, a pressure sensor, an acceleration sensor, or a sound sensor, for example. In this case, the lid does not need to be transparent. Furthermore, the semiconductor element may be fabricated by MEMS.

Libs having upper surfaces on which connection electrodes to be electrically connected to a semiconductor element are formed may be placed at all the four sides of the rectangular package.

The shape of the upper surface of the transparent member placed on the semiconductor element is not limited to rectangles and circles, and may be a polygon such as a triangle and a pentagon, an oval, or any shape in which a circle or an oval is partially cut off along a line as long as light reaches the entire light-receiving surface.

In the optical pickup module illustrated in FIGS. 13 and 14, the semiconductor devices (photodetectors) of the second through sixth embodiments may be employed.

In the method for fabricating the semiconductor device 2 of the second embodiment, the package-assembled board provided with a plurality of trenches may be replaced by a package-assembled board provided with a plurality of recesses. In this case, semiconductor elements are housed in the recesses, and the package-assembled board is cut with ribs and plate-like side walls left, thereby obtaining semiconductor devices.

In the semiconductor device 2 of the second embodiment, the height of the plate-like side walls 30 is not specifically limited. The top of the plate-like side walls 30 may reach the side surfaces of the lid 90, or may be at a half level of the height illustrated in FIGS. 4 and 5.

### INDUSTRIAL APPLICABILITY

As described above, a semiconductor device according to the present invention can be miniaturized, and is useful as, for example, a photodetector for use in an optical pickup module.

1. A semiconductor device, comprising:
a semiconductor element; and
a package on which the semiconductor element is mounted, wherein the package includes
a base which is substantially rectangular and has a mounting surface on which the semiconductor element is mounted, and
ribs respectively provided on a pair of opposite external edges of the mounting surface and extending along the opposite external edges,
a connection electrode and a spacer are provided on an upper surface of each of the ribs, the connection electrode is connected to the semiconductor element by a metal wire, and
the spacer is located farther from the semiconductor element than the connection electrode, has a height greater than a diameter of the metal wire, and extends along an external edge of the upper surface of the rib.

2. The semiconductor device of claim 1, wherein a side wall surface of each of the ribs extending along one of the external edges of the mounting surface on which the rib is provided is flush with an external side wall surface of the spacer extending along the external edge of the upper surface of the rib.

3. The semiconductor device of claim 1, wherein the spacer has a height smaller than or equal to twice as large as the diameter of the metal wire.

4. The semiconductor device of claim 1, wherein the metal wire is buried in an encapsulating resin.

5. The semiconductor device of claim 4, wherein the semiconductor element is an optical element, and
a transparent member is placed on the semiconductor element.

6. The semiconductor device of claim 5, wherein the transparent member has a shape of a plate having a side surface buried in the encapsulating resin and having an exposed upper surface.

7. The semiconductor device of claim 5, wherein a distance from the mounting surface to an upper surface of the transparent member is larger than a distance from the mounting surface to an upper surface of the spacer.

8. The semiconductor device of claim 1, wherein a lid is placed on, and adheres to, the spacer.

9. The semiconductor device of claim 8, wherein a portion of the lid located on the spacer has a surface which is flush which an external side wall surface of the spacer extending along the external edge of the upper surface of the rib.

10. The semiconductor device of claim 8, wherein a portion of the metal wire which is not in contact with any of the connection electrode and the semiconductor element is exposed to air.

11. The semiconductor device of claim 8, wherein an adhesive that bonds the lid and the spacer at least partially covers a portion of the metal wire in contact with the connection electrode.

12. The semiconductor device of claim 8, wherein plate-like side walls extending along another pair of external edges of the mounting surface from one of the ribs to the other rib is further provided, and
a width of an upper surface of each of the plate-like side walls orthogonal to the another pair of external edges of the mounting surface is smaller than a width of the upper surface of each of the ribs orthogonal to the pair of external edges of the mounting surface.

13. The semiconductor device of claim 8, wherein the semiconductor element is an optical element, and
the lid is made of a transparent material.

14. A method for fabricating a semiconductor device including a semiconductor element and a package on which the semiconductor element is mounted, the method comprising:
preparing a package-assembled board including
a plurality of parallel trenches,
two lines of connection electrodes provided on an upper surface of a side wall of each of the trenches and arranged along the trench, and
a spacer provided between the two lines of connection electrodes and extending along the trench;
placing a plurality of semiconductor elements in each of the trenches in a direction along which the trench extends;
connecting the semiconductor element and the connection electrodes to each other by metal wires; and
cutting the package-assembled board along a line between the two lines of connection electrodes, thereby dividing the package-assembled board.

15. The method of claim 14, further comprising placing a lid on the spacer and bonding the lid to the spacer.

16. The method of claim 14, further comprising:
placing a transparent member in the shape of a plate on the semiconductor element; and
encapsulating the metal wires and a side wall surface of the transparent member with an encapsulating resin.

17. An optical pickup module, comprising:
the semiconductor device recited in claim 1;
a laser module; and
a beam splitter, wherein
the semiconductor element included in the semiconductor device is a photoreceiver.

18. The optical pickup module of claim 17, further comprising a mirror and an objective lens.

19. The optical pickup module of claim 17, wherein the optical pickup module is placed under an information-recording surface of an optical disk, and
a direction along which the ribs extend is substantially perpendicular to the information-recording surface.

20. The optical pickup module of claim 17, wherein
the laser module includes:
a blue-violet laser device configured to emit light having a peak wavelength ranging from 385 nm to 425 nm, both inclusive; and
a dual-wavelength laser device configured to emit light having a peak wavelength ranging from 630 nm to 670 nm, both inclusive, and light having a peak wavelength ranging from 760 nm to 800 nm, both inclusive.
